(19) United States
(12) Patent Application Publication
(10) Pub. No.: US 2004/0133834 A1
(43) Pub. Date: Jul. 8, 2004

(54) Lsi inspection method and apparatus, and ls1 tester

(76) Inventors: Tomohiko Kanemitsu, Osaka (JP); Wataru Ito, Kyoto (JP); Akihiko Watanabe, Osaka (JP); Shiro Nozaki, Osaka (JP); Tomomitsu Masuda, Osaka (JP)

Correspondence Address: McDermott Will & Emery, 600 13th Street NW, Washington, DC, 20005-3096, US

(21) Appl. No.: 10/475,327

(22) PCT Filed: Oct. 4, 2002
(86) PCT No.: PCT/JP02/10389

(30) Foreign Application Priority Data
Oct. 5, 2001 (JP) 2001-309629

(51) Int. Cl. G06F 11/00; G01R 31/28

(52) U.S. Cl. 714/742

(57) ABSTRACT

A test of an LSI device under test (20) including a physical layer section (21) which has a high-speed interface function is performed. An LSI device test unit (1) including a reference LSI device (10) which has already been confirmed as being non-defective is placed on a test board (2), and high-speed pins of the LSI devices (10, 20) are connected to each other. An LSI tester (3) accesses logical layer sections (12, 22) at a low speed to control a high-speed communication between physical layer sections (11, 21) and read received data, and determines whether or not the LSI device under test (20) is defective.

### TECHNICAL FIELD

The present invention relates to a test of an LSI device incorporating a high-speed interface.

### BACKGROUND ART

Conventionally, a test of an LSI device incorporating a high-speed interface, such as an IEEE1394 interface, a USB, or the like, has been performed such that a high-speed signal is directly supplied from an LSI tester to the LSI device, and a high-speed signal output from the LSI device is directly input to the LSI tester (see, for example, Japanese Patent No. 3058130).

FIG. 9 shows a structure of a conventional LSI device test system. In FIG. 9, a test is performed on a physical layer section 21 of an LSI device 20 to be tested (“LSI device 20 under test”) which is mounted on a test board 52. The LSI device 20 under test has a high-speed interface function.

In a signal reception test for the physical layer section 21, a high-speed signal is directly transmitted from an LSI tester 53 to the physical layer section 21. The physical layer section 21 converts the received high-speed signal to a low-speed signal by a conversion method, such as deserialization, or the like, and supplies the low-speed signal to the LSI tester 53 through a logical layer section 22 which interfaces at a low speed. The LSI tester 53 determines whether or not the LSI device 20 is defective based on the received low-speed signal. In a signal transmission test for the physical layer section 21, a low-speed signal is supplied from the LSI tester 53 to the physical layer section 21 through the logical layer section 22. The physical layer section 21 converts the received low-speed signal to a high-speed signal by a conversion method, such as serialization, or the like, and transmits the high-speed signal to the LSI tester 53. The LSI tester 53 determines whether or not the LSI device 20 is defective based on the received high-speed signal.

### Problems to be Solved

However, in the above-described conventional technique, a test of a high-speed interface LSI device requires a high-speed LSI tester which is capable of interfacing at a high speed. In general, a high-speed LSI tester is expensive as compared with a low-speed LSI tester which interfaces at a low speed, and therefore causes an increase in the test cost.

In another possible method, a high-speed signal generation circuit, an expected value comparison circuit, a test control circuit, etc., are incorporated in the LSI device under test itself for the purpose of achieving a test with a low-speed LSI tester. However, in this case, it is difficult to perform a test of the high-speed circuits incorporated in the LSI device under test. Thus, when a test of the circuits is not sufficiently performed, there is a possibility of erroneously determining a defective product to be non-defective. Furthermore, an increase of the LSI device area causes an increase in cost.

In view of the above problems, an objective of the present invention is to realize a test of a high-speed interface LSI device at a low test cost and at a high test assurance level.

### Disclosure of Invention

According to the present invention, in a conventional structure, a reference device having a physical layer section and a logical layer section is placed between an LSI tester and an LSI device under test which interface with each other at a high speed for conducting a test of the LSI device under test. With this arrangement, the LSI tester does not need to interface at a high speed, and therefore, an LSI device incorporating a high-speed interface can be tested with a low-speed tester. Accordingly, an increase in the test cost is prevented. Moreover, it is not necessary to confirm for every test whether or not the reference device is defective. It is only necessary to perform such a confirmation at least one time with a high frequency measurement device or high-speed LSI tester. Therefore, the test can be achieved readily and surely at a high test assurance level.

Specifically, the present invention is directed to an LSI device test method for testing an LSI device under test which includes a physical layer section having a high-speed interface function, the method comprising the steps of: mounting the LSI device under test on a test board that is capable of interfacing with an LSI tester, the test board including a first reference device which has a physical layer section and a logical layer section, the physical layer section having a function equivalent to the high-speed interface function, and the logical layer section being connected to the physical layer section and having a low-speed interface function; electrically connecting the physical layer section of the first reference device and the physical layer section of the LSI device under test to each other; executing a high-speed communication between the physical layer section of the first reference device and the physical layer section of the LSI device under test by establishing signal transmission and reception settings of the first reference device and the LSI device under test by the LSI tester; and reading a signal received by the first reference device or the LSI device under test with the LSI tester.

In the LSI test method of the present invention, it is preferable that: the LSI device under test includes a logical layer section which is connected to the physical layer section of the LSI device under test and which has a low-speed interface function; and the LSI tester performs establishment of the transmission and reception settings and reading of the received signal through the logical layer section of the first reference device and the logical layer section of the LSI device under test.

In the LSI test method of the present invention, it is preferable that: the test board includes a second reference device having a logical layer section, the logical layer section being connected to the physical layer section of the LSI device under test and having a low-speed interface function; and the LSI tester performs establishment of the transmission and reception settings and reading of the received signal through the logical layer section of the first reference device and the logical layer section of the second reference device.

In the LSI test method of the present invention, it is preferable that the supply voltage applied to the first reference device is different from that applied to the LSI device under test.

In the LSI test method of the present invention, it is preferable that prior to establishment of the transmission and reception settings, the LSI tester confirms the internal statuses of the first reference device and the LSI device under test. Furthermore, it is preferable that the confirmation of the internal statuses is achieved by reading data from internal storage sections of the first reference device and the LSI device under test. Alternatively, it is preferable that when the internal statuses do not settle into predetermined statuses within a predetermined time period, the LSI tester determines that the LSI device under test is defective.

In the LSI test method of the present invention, it is preferable that prior to reading of the received signal, the LSI tester confirms completion of the communication at the first reference device or the LSI device under test. Furthermore, it is preferable that the confirmation of completion of the communication is achieved by reading data from an internal storage section of the first reference device or the LSI device under test.

The present invention is also directed to an LSI device test system for testing an LSI device under test which includes at least a physical layer section having a high-speed interface function, the system being structured to be mountable on a test board which is capable of interfacing with an LSI tester and on which the LSI device under test is mounted, and comprising: a first reference device including a physical layer section having a function equivalent to the high-speed interface function, and a logical layer section which is connected to the physical layer section of the first reference device and which has a low-speed interface function; and connection means for electrically connecting the physical layer section of the first reference device and the physical layer section of the LSI device under test.

Preferably, the LSI device test system of the present invention further comprises a second reference device which is placed between the physical layer section of the LSI device under test and the LSI tester and which includes a logical layer section having a low-speed interface function.

In the LSI device test system of the present invention, it is preferable that the first reference device includes a first reference LSI device having the physical layer section, and a second reference LSI device having the logical layer section.

In the LSI device test system of the present invention, it is preferable that the connection means includes means for branching a signal path formed between the first reference device and the LSI device under test.

In the LSI device test system of the present invention, it is preferable to further comprise a clock generator for supplying a clock to the LSI device under test and the first reference device independently of the operation of the LSI tester.

In the LSI device test system of the present invention, it is preferable that the first reference device is already confirmed as being non-defective.

In the LSI device test system of the present invention, it is preferable that the first reference device provides the lowest performance satisfying assurance specifications.

The present invention is also directed to an LSI tester for testing an LSI device under test which includes at least a physical layer section having a high-speed interface function, the LSI tester being capable of interfacing with a test board on which the LSI device under test is mounted, and comprising a first reference device including a physical layer section which has a function equivalent to the high-speed interface function, and a logical layer section which is connected to the physical layer section of the first reference device and which has a low-speed interface function; and a high-speed interface port which is electrically connected to the physical layer section of the first reference device and which executes a high-speed communication with the test board.

Preferably, the LSI tester of the present invention further comprises: a low-speed interface port for executing a low-speed communication with the test board; and a second reference device including a logical layer section which is connected to the low-speed interface port and which has a low-speed interface function.

### BRIEF DESCRIPTION OF DRAWINGS

FIG. 1 shows a structure of an LSI device test system according to embodiment 1 of the present invention.

FIG. 2 is a flowchart which illustrates the operation of an LSI tester.

FIG. 3 shows a specific structure example of an LSI device test system according to the present invention.

FIG. 4 shows a structure of an LSI device test system according to embodiment 2 of the present invention.

FIG. 5 shows a structure of an LSI device test system according to embodiment 3 of the present invention.

FIG. 6 shows a structure of an LSI device test system according to embodiment 4 of the present invention.

FIG. 7 is a flowchart which illustrates the operation of an LSI tester according to embodiment 5 of the present invention.

FIG. 8 shows a structure of an LSI device test system according to embodiment 6 of the present invention.

FIG. 9 shows a structure of a conventional LSI device test system.

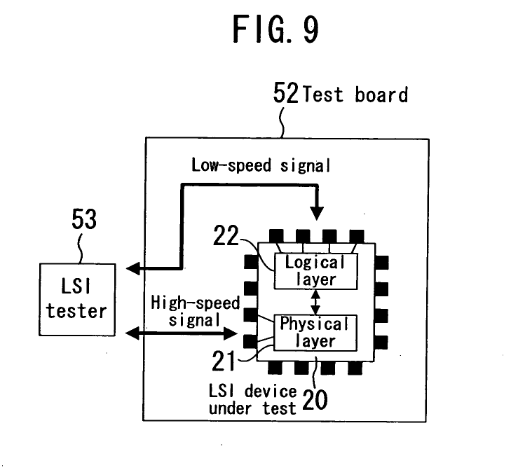

### BEST MODE FOR CARRYING OUT THE INVENTION

Hereinafter, embodiments of the present invention are described with reference to the drawings. In the specification of the present application, a “high-speed interface” specifically refers to an interface, such as an IEEE1394 interface, a USB, or the like, which has a communication speed of about several hundreds of megabits per second (Mbps) or higher. A “low-speed interface” refers to an interface having a communication speed of about several tens of megabits per second (Mbps) or lower.

### Embodiment 1

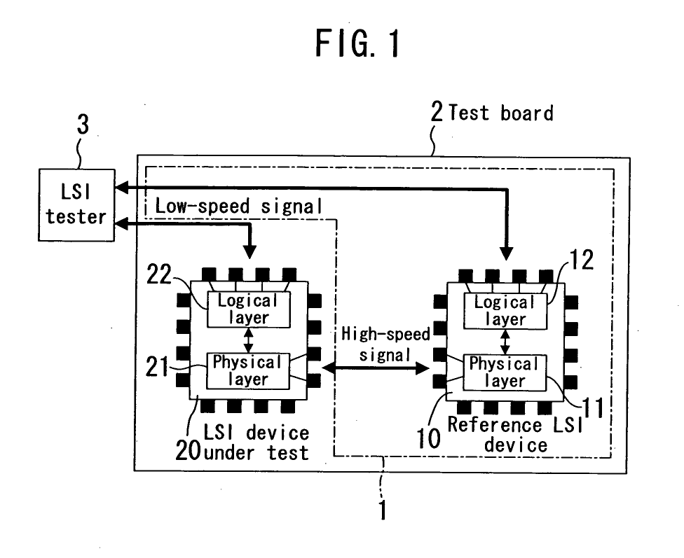

FIG. 1 shows a structure of an LSI device test system according to embodiment 1 of the present invention. In FIG. 1, an LSI device 20 under test includes a physical layer section 21 and a logical layer section 22. The physical layer section 21 includes a function of interfacing with devices outside the LSI device 20 under test at a high speed. The logical layer section 22 is connected to the physical layer section 21 and includes a function of interfacing with devices outside the LSI device 20 under test at a low speed. For example, an IEEE1394a-2000-based LSI device includes a driver and receiver for high-speed signals, a serializer, a deserializer, an arbitration circuit, etc., in a physical layer section, and a link layer, a memory, a microcomputer interface, etc., in a logical layer section.

The LSI device 20 under test is mounted on a test board 2 which is capable of interfacing with a LSI tester 3. The LSI tester 3 and the LSI device 20 under test are electrically connected to each other through pins which are required to access the logical layer section 22. Further, an LSI device test unit 1 is mounted on the test board 2. The LSI device test unit 1 includes a reference LSI device (first reference device) 10. The reference LSI device 10 has a physical layer section 11 and a logical layer section 12. The physical layer section 11 interfaces with devices outside the reference LSI device 10 at a high speed. The logical layer section 12 is connected to the physical layer section 11 and includes a function of interfacing with devices outside the reference LSI device 10 at a low speed. The high-speed interfacing function of the physical layer section 11 is equivalent to that of the physical layer section 21 of the LSI device 20 under test.

Between the LSI device 20 under test and the reference LSI device 10, high-speed pins are interconnected so that high-speed interfacing is achieved. This interconnection may be patterned on the test board 2. Alternatively, the interconnection may be established by a cable. The LSI tester 3 and the reference LSI device 10 are electrically connected through pins which are required to access the logical layer section 12. Herein, the first reference device of the present invention is realized by a single reference LSI device 10.

It is assumed herein that the reference LSI device 10 has already been confirmed as being non-defective by an LSI tester which is capable of testing a high-speed interface, a high-frequency measuring device, or the like. The LSI device 20 under test and the reference LSI device 10 may have the same structure. The electric power is supplied to the LSI device 20 under test and the reference LSI device 10 from the LSI tester 3.

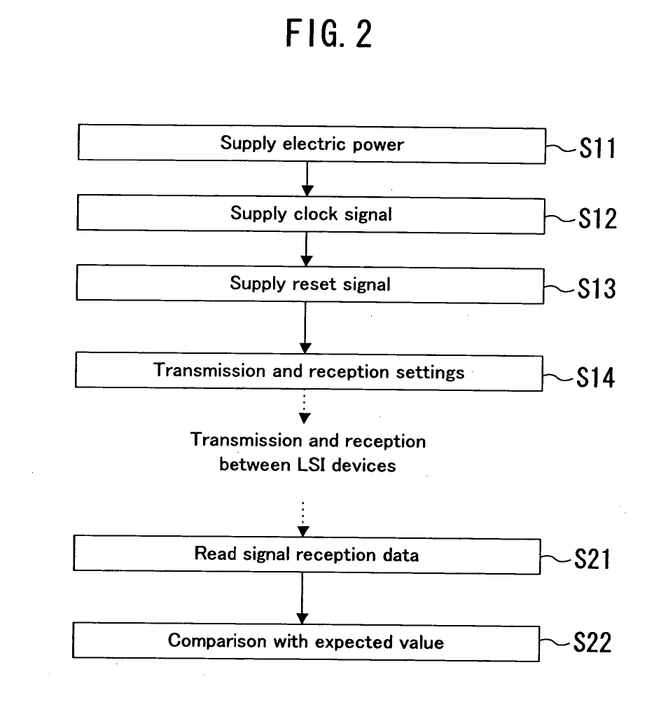

FIG. 2 is a flowchart which illustrates the operation of the LSI tester 3. An test method of embodiment 1 for testing the LSI device 20 under test is described with reference to FIG. 2.

In the first place, a signal transmission test for the physical layer section 21 is described. The LSI tester 3 sequentially supplies a predetermined test voltage (S11), a clock signal (S12) and a reset signal (S13) to the LSI device 20 under test and the reference LSI device 10. Thereafter, the LSI tester 3 accesses the logical layer section 22 of the LSI device 20 under test and the logical layer section 12 of the reference LSI device 10 using a low-speed signal to establish transmission and reception settings (S14). According to the transmission and reception settings, a high-speed signal is transmitted from the physical layer section 21 of the LSI device 20 under test to the physical layer section 11 of the reference LSI device 10.

The physical layer section 11 of the reference LSI device 10 converts the received high-speed signal to a low-speed signal through a conversion process, such as deserialization, or the like, and outputs the low-speed signal as signal reception data to the logical layer section 12. The LSI tester 3 accesses the logical layer section 12 to read the data received by the reference LSI device 10 (S21). The LSI tester 3 then compares the read data with an expected value to determine whether or not the LSI device 20 under test is defective based on the result of comparison (S22).

Next, a signal reception test for the physical layer section 21 is described. In this test, the LSI tester 3 operates as illustrated in FIG. 2, but the object of control is different from that of the signal transmission test. The LSI tester 3 sequentially supplies a predetermined test voltage (S11), a clock signal (S12) and a reset signal (S13) to the reference LSI device 10 and the LSI device 20 under test. Thereafter, the LSI tester 3 accesses the logical layer section 22 and the logical layer section 12 with a low-speed signal to establish transmission and reception settings (S14). According to the transmission and reception settings, a high-speed signal is transmitted from the physical layer section 11 of the reference LSI device 10 to the physical layer section 21 of the LSI device 20 under test.

The physical layer section 21 of the LSI device 20 under test converts the received high-speed signal to a low-speed signal through a conversion process, such as deserialization, or the like, and outputs the low-speed signal as signal reception data to the logical layer section 22. The LSI tester 3 accesses the logical layer section 22 to read the data received by the LSI device 20 under test (S21). The LSI tester 3 then compares the read data with an expected value to determine whether or not the LSI device 20 under test is defective based on the result of comparison (S22).

As described above, according to embodiment 1, the signal transmission and reception tests for the physical layer section 21 of the LSI device 20 under test, which interfaces with a high-speed signal, can be realized by the communication of a low-speed signal between the LSI tester 3 and the test board 2. On the other hand, tests for the logical layer section 22 are realized at the same time with the signal transmission and reception tests for the physical layer section 21. Thus, a test of mass-produced, high-speed interface LSI devices can be achieved only with an inexpensive LSI tester having a low-speed interface and a simple-structured LSI device test unit mounted on a test board. Therefore, an increase in the test cost can be prevented.

The present invention is applicable to a test of a physical layer of an IEEE1394 interface, a USB, or the like. For example, in an IEEE1394a-2000-based LSI device, the communication speed of a high-speed interface is about 400 Mbps, and the communication speed of a low-speed interface is about 25 Mbps. Thus, according to the present invention, a test of mass-produced LSI devices can be realized with an inexpensive LSI tester which is capable of interfacing at about 25 Mbps, without using an expensive LSI tester which is capable of interfacing at about 400 Mbps.

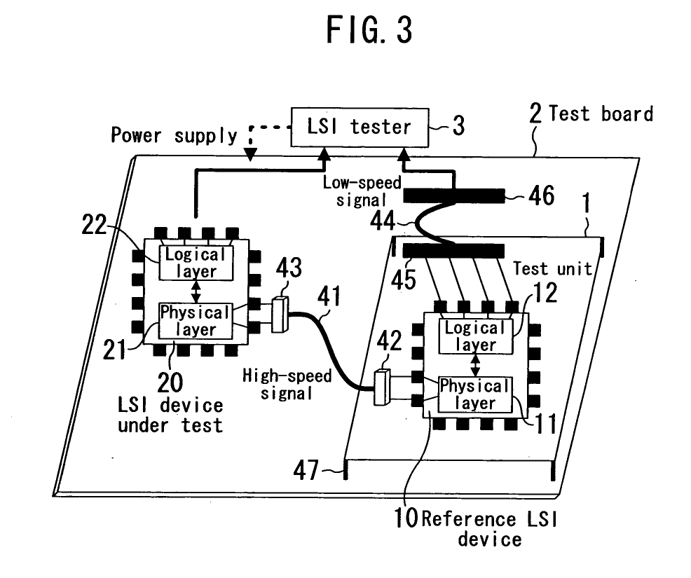

FIG. 3 shows a specific structure example of the LSI device test system according to embodiment 1. In FIG. 3, the LSI device test unit 1 incorporating the reference LSI device 10 is fixed to the test board 2 using pillars 47. The physical layer section 11 of the reference LSI device 10 and the physical layer section 21 of the LSI device 20 under test are connected to each other through connection means, i.e., a cable 41 and connectors 42 and 43. The logical layer section 12 of the reference LSI device 10 is connected to the LSI tester 3 through a cable 44 and connectors 45 and 46.

### Embodiment 2

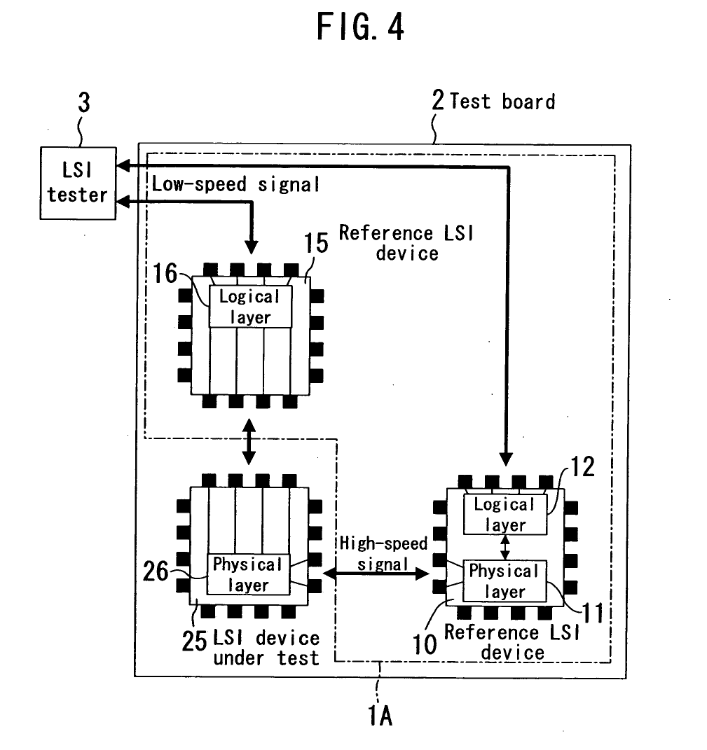

FIG. 4 shows a structure of an LSI device test system according to embodiment 2 of the present invention. In FIG. 4, like elements are denoted by like reference numerals used in FIG. 1. In FIG. 4, an LSI device 25 under test does not include a logical layer section but only a physical layer section 26. An LSI device test unit 1A includes a reference LSI device (second reference device) 15 in addition to the reference LSI device 10 described in embodiment 1. The reference LSI device 15 includes a logical layer section 16 having a low-speed interface function.

Between the LSI device 25 under test and the reference LSI device 10, high-speed pins thereof, which interface at a high speed, are interconnected. This interconnection may be patterned on the test board 2. Alternatively, the interconnection may be established by a cable. The LSI tester 3 and the reference LSI device 10 are connected through pins which are required to access the logical layer section 12.

The reference LSI device 15 is connected to a pin of the LSI device 25 under test so as to interface with a physical layer section 26 of the LSI device 25 under test. The LSI tester 3 and the reference LSI device 15 are electrically connected through pins which are required to access the logical layer section 16. That is, the reference LSI device 15 is present between the physical layer section 26 of the LSI device 25 under test and the LSI tester 3.

It is assumed herein that the reference LSI device 10 has already been confirmed as being non-defective by an LSI tester which is capable of testing a high-speed interface, a high-frequency measuring device, or the like. It is assumed herein that the reference LSI device 15 has already been confirmed as being non-defective by an LSI tester, a measuring device, or the like, which is capable of testing a logical layer. The electric power is supplied to the LSI device 25 under test and the reference LSI devices 10 and 15 from the LSI tester 3.

In the first place, a signal transmission test for the physical layer section 26 is described. The LSI tester 3 operates as illustrated in FIG. 2. The LSI tester 3 sequentially supplies a predetermined test voltage (S11), a clock signal (S12) and a reset signal (S13) to the LSI device 25 under test and the reference LSI devices 10 and 15. Thereafter, the LSI tester 3 accesses the logical layer section 16 of the reference LSI device 15 and the logical layer section 12 of the reference LSI device 10 with a low-speed signal to establish transmission and reception settings (S14). According to the transmission and reception settings, a high-speed signal is transmitted from the physical layer section 26 of the LSI device 25 under test to the physical layer section 11 of the reference LSI device 10.

The physical layer section 11 of the reference LSI device 10 converts the received high-speed signal to a low-speed signal through a conversion process, such as deserialization, or the like, and outputs the low-speed signal as signal reception data to the logical layer section 12. The LSI tester 3 accesses the logical layer section 12 to read the data received by the reference LSI device 10 (S21). The LSI tester 3 then compares the read data with an expected value to determine whether or not the LSI device 25 under test is defective based on the result of comparison (S22).

Next, a signal reception test for the physical layer section 26 is described. The LSI tester 3 sequentially supplies a predetermined test voltage (S11), a clock signal (S12) and a reset signal (S13) to the reference LSI devices 10 and 15 and the LSI device 25 under test. Thereafter, the LSI tester 3 accesses the logical layer section 16 and the logical layer section 12 with a low-speed signal to establish transmission and reception settings (S14). According to the transmission and reception settings, a high-speed signal is transmitted from the physical layer section 11 of the reference LSI device 10 to the physical layer section 26 of the LSI device 25 under test.

The physical layer section 26 of the LSI device 25 under test converts the received high-speed signal to a low-speed signal through a conversion process, such as deserialization, or the like, and outputs the low-speed signal as signal reception data to the logical layer section 16 of the reference LSI device 15. The LSI tester 3 accesses the logical layer section 16 to read the data received by the LSI device 25 under test (S21). The LSI tester 3 then compares the read data with an expected value to determine whether or not the LSI device 25 under test is defective based on the result of comparison (S22).

As described above, according to embodiment 2, the signal transmission and reception tests for the physical layer section 26 of the LSI device 25 under test, which interfaces with a high-speed signal, can be realized by the communication of a low-speed signal between the LSI tester 3 and the test board 2 even when a logical layer is not present in the LSI device 25. Thus, a test of mass-produced, high-speed interface LSI devices having only physical layers can be achieved only with an inexpensive LSI tester having a low-speed interface and a simple-structured LSI device test unit mounted on a test board. Therefore, an increase in the test cost can be prevented.

In embodiments 1 and 2, a single reference LSI device 10 is used as the first reference device of the present invention. However, the first reference device may be formed by a first reference LSI device having a physical layer section 11 and a second reference LSI device having a logical layer section 12 instead.

The LSI test processes of embodiment 1 and 2 require a slightly longer test time as compared with conventional test processes. However, in many cases, the cost merit of using an inexpensive LSI tester is more significant than the demerit of increasing the test time.

For example, it may be possible that the control function and defect/non-defect determination function of an LSI tester are delegated to other elements mounted on a test board, and the LSI tester is replaced with a less expensive, simple LSI tester having reduced functions. However, in such a method, the cost of the test board and the maintenance cost are increased. Thus, if LSI devices other than the high-speed interface LSI devices cannot be tested with the simple LSI tester, the test cost is lower in embodiment 1 and 2.

In embodiment 1 and 2, the signal transmission and reception tests for a physical layer section have been described. However, in actual mass production of LSI devices, it is necessary to conduct the tests for functions of the other circuits and DC tests, such as a current leakage test, or the like. In this case, in the structure of FIG. 1 or FIG. 4, a pin other than the high-speed pins of the LSI device 20 under test is connected to the LSI tester 3, whereby the above test can be conducted.

### Embodiment 3

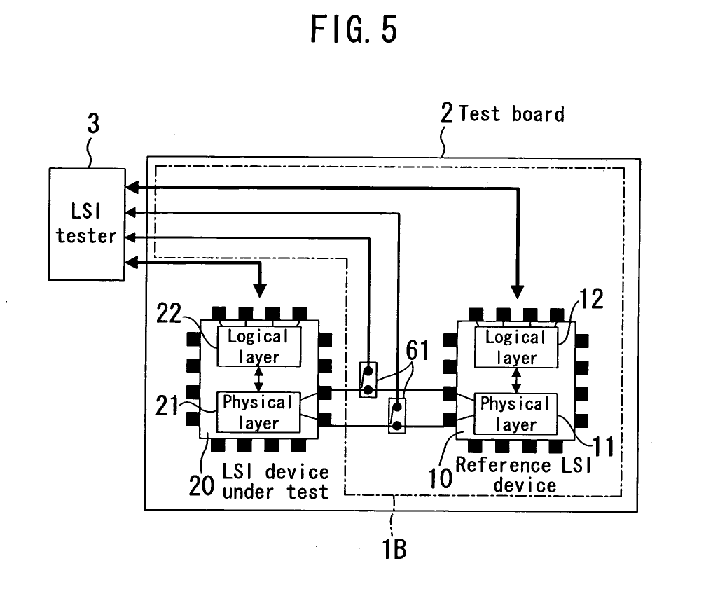

In Embodiment 3, DC tests for a driver and receiver of a physical layer section can be performed in addition to the signal transmission and reception tests for the physical layer section which have been described in embodiments 1 and 2. The DC tests for the driver include an output voltage test, an output current test, etc. The DC tests for the receiver include a threshold voltage test, etc. These tests are necessary for assuring the capacity of the driver or the receiver. FIG. 5 shows a structure of an LSI device test system according to embodiment 3. In FIG. 5, like elements are denoted by like reference numerals used in FIG. 1. Comparing FIG. 5 with FIG. 1, the structure of FIG. 5 is different from that of FIG. 1 in that relays (branch means) 61 are provided in interconnections between high-speed pins of the LSI device 20 under test and the reference LSI device 10, and that branched connections are provided from the physical layer section 21 of the LSI device 20 to the LSI tester 3 through the relays 61. In the structure of FIG. 5, the signal transmission and reception tests for the physical layer section 21 are performed when the relays 61 are turned off, and the DC tests for the driver and receiver of the physical layer section 21 are performed when the relays 61 are turned on.

The signal transmission and reception tests for the physical layer section 21 are the same as those of embodiment 1 except that the relays 61 are turned off before the tests are started. If the relays 61 are left to be on, long branched connections to the LSI tester 3 exist and this can cause a distortion in the waveform of a signal transmitted/received at a high speed. As a result, appropriate signal transmission and reception tests cannot be performed. Note that the relays 61 should be arranged such that the branched connections are shortest when the relays 61 are turned off.

A method for performing the DC tests for a driver and receiver of the physical layer section 21 is described. The LSI tester 3 sequentially supplies a predetermined test voltage, a clock signal and a reset signal to the LSI device 20 under test and the reference LSI device 10. Thereafter, the LSI tester 3 sets the LSI device 20 under test to a mode such that the DC tests for the driver and receiver of the physical layer section 21 can be performed. On the other hand, in the reference LSI device 10, the driver and receiver of the physical layer section 11 are set to a high impedance state. In this state, the relays 61 are turned on so that the LSI tester 3 and the high-speed pin of the LSI device 20 under test are electrically connected through the relays 61, and the DC tests are performed using an ammeter and voltmeter of the LSI tester 3.

As described above, according to embodiment 3, not only the signal transmission and reception tests for the physical layer section 21 which interfaces with a high-speed signal, but also the DC tests for the driver and receiver of the physical layer section 21 can be performed. Thus, the test assurance level can be increased. As a matter of course, the DC tests for the driver and receiver of the physical layer section 21 may be carried out at another step on another test board. However, such a process causes an increase in the test cost. On the other hand, according to embodiment 3, an increase in the test cost is suppressed.

### Embodiment 4

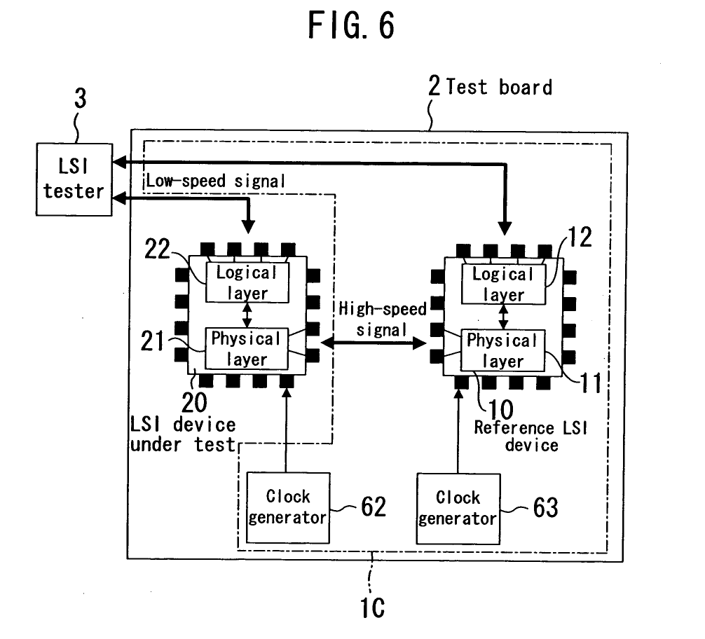

FIG. 6 shows a structure of an LSI device test system according to embodiment 4 of the present invention. In FIG. 6, like elements are denoted by like reference numerals used in FIG. 1. Comparing FIG. 6 with FIG. 1, the structure of FIG. 6 is different from that of FIG. 1 in that an LSI device test unit 1C includes clock generators 62 and 63 for supplying clocks to the LSI device 20 under test and the reference LSI device 10, respectively. That is, according to embodiment 4, in the signal transmission and reception tests for the physical layer section which have been described in embodiment 1, clocks independent from the operation of the LSI tester 3 can be supplied to the LSI device 20 under test and the reference LSI device 10.

For example, when the signal transmission and reception tests for the physical layer are carried out under a plurality of test conditions, the test duration is reduced if the test conditions are changed without stopping the supply of clocks to the respective LSI devices. Especially in the IEEE1394a-2000 standards, a bus reset occurs and bus arbitration is conducted every time the supply of clock(s) is stopped. Thus, stoppage of clock(s) greatly influences the test time. On the other hand, many LSI testers cannot continue to supply a clock when the test conditions are changed or when the function test pattern is switched.

Thus, in embodiment 4, the test system is arranged such that clocks independent from the LSI tester 3 can be supplied to the LSI device 20 under test and the reference LSI device 10. With this arrangement, the clocks can be supplied to the LSI device 20 under test and the reference LSI device 10 without an interruption even when the test conditions are changed. Thus, an increase in the test time is suppressed, and an increase in the test cost is prevented.

### Embodiment 5

According to embodiment 5, in the signal transmission and reception tests for the physical layer section which have been described in embodiment 1, the operation of the LSI tester is controlled adaptively according to the statuses of an LSI device under test and a reference LSI device. Embodiment 5 is suitable to a type of high-speed interface which automatically performs bus arbitration.

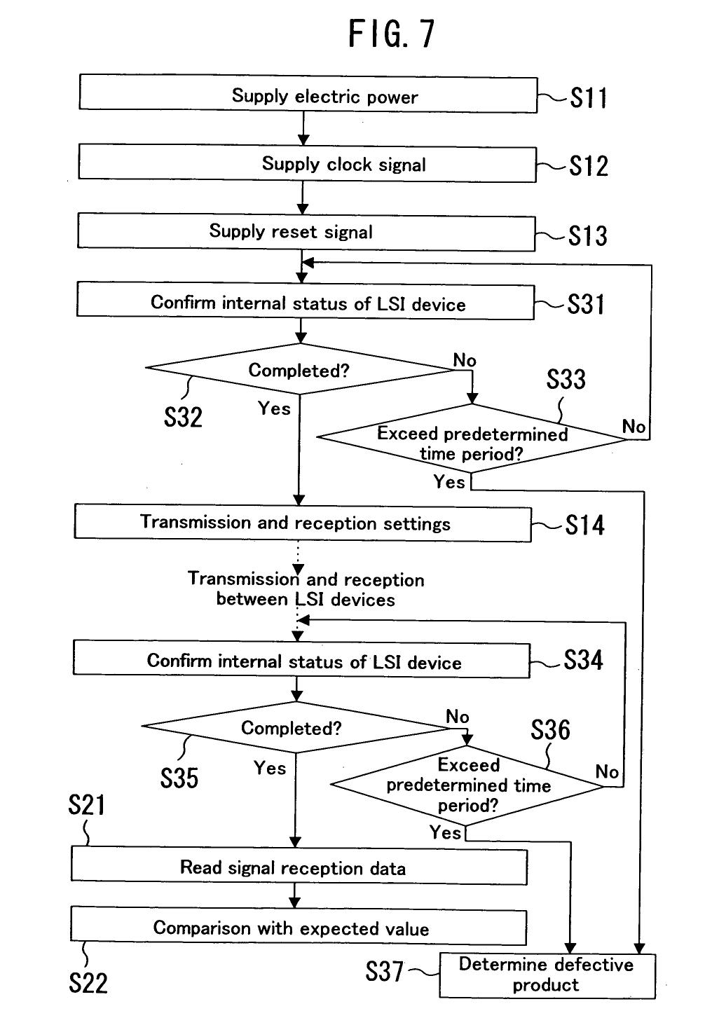

FIG. 7 is a flowchart which illustrates the operation of an LSI tester 3 according to embodiment 5. Comparing the flow of FIG. 7 with that of FIG. 2 of embodiment 1, the flow of FIG. 7 is different in that, the internal statuses of an LSI device under test and a reference LSI device are confirmed and the control operation performed thereafter is determined according to the internal statuses before establishment of the transmission and reception settings (S14) and before reading of the signal reception data (S21). It should be noted that the structure of an LSI test system used in embodiment 5 is the same as that illustrated in FIG. 1.

In the case of a high-speed interface which automatically performs bus arbitration, the arbitration is started after a reset signal is input. In the arbitration procedure, recognition of the number of nodes connected to a bus, allocation of node IDs, etc., are performed, and transmission/reception of a signal cannot be performed until the end of the arbitration procedure. Since the time required for the arbitration can be estimated to some extent, a sufficient latency time may be provided before the next transmission and reception settings. But, even in such a method, there is a possibility that the time required for the arbitration greatly varies according to the individual differences of LSI devices under test and the environmental conditions. Therefore, establishing the transmission and reception settings after it is confirmed whether or not the arbitration has been completed is more effective in view of the test time and the stability of the test.

Also in transmission/reception of a signal, some variation occurs in the completion time of the signal transmission/reception according to the individual differences of LSI devices under test and the environmental conditions. Thus, reading signal reception data after it is confirmed whether or not the signal transmission/reception has been completed is more effective in view of the test time and the stability of the test.

In the first place, a signal transmission test for the physical layer section 21 is described. As described in embodiment 1, the LSI tester 3 sequentially supplies a predetermined test voltage (S11), a clock signal (S12) and a reset signal (S13) to the LSI device 20 under test and the reference LSI device 10.

The LSI tester 3 confirms the internal statuses of the LSI device 20 under test and the reference LSI device 10, i.e., whether or not the arbitration operation has been completed (S31). This confirmation can be realized by observing an external terminal through which the internal status can be monitored or by reading data from an internal storage section for storing the number of nodes or node IDs, such as an internal register, an internal memory, etc. If the arbitration operation has not been completed (No at S32), the confirmation operation is performed again (S33, S31). As a matter of course, the reset signal may be supplied to the LSI device 20 under test and the reference LSI device 10 again. If the arbitration has not been completed within a predetermined time period (Yes at S33), the LSI device 20 under test is determined to be defective (S37).

If completion of the arbitration is confirmed (Yes at S32), the LSI tester 3 accesses the logical layer section 22 of the LSI device 20 under test and the logical layer section 12 of the reference LSI device 10 with a low-speed signal to establish transmission and reception settings, respectively (S14). According to the transmission and reception settings, a high-speed signal is transmitted from the physical layer section 21 of the LSI device 20 under test to the physical layer section 11 of the reference LSI device 10. The physical layer section 11 of the reference LSI device 10 converts the received high-speed signal to a low-speed signal through a conversion process, such as deserialization, or the like, and outputs the low-speed signal as signal reception data to the logical layer section 12.

Then, the LSI tester 3 again confirms the internal status of the reference LSI device 10, i.e., whether or not the signal receiving operation has been completed (S34). This confirmation can also be realized by observing an external terminal through which the internal status can be monitored or by reading data from an internal storage section for storing the number of nodes or node IDs, such as an internal register, an internal memory, etc. If the signal receiving operation has not been completed (No at S35), the confirmation operation is performed again (S36, S34). As a matter of course, the signal may be transmitted from the physical layer section 21 to the physical layer section 11 again. If the signal reception has not been completed within a predetermined time period (Yes at S36), the LSI device 20 under test is determined to be defective (S37).

If completion of the signal reception is confirmed (Yes at S35), the LSI tester 3 accesses the logical layer section 12 of the reference LSI device 10 to read data received by the reference LSI device 10 (S21). The LSI tester 3 then compares the read data with an expected value to determine whether or not the LSI device 20 under test is defective based on the result of comparison (S22).

Next, a signal reception test for the physical layer section 21 is described. In this test, the LSI tester 3 operates as illustrated in FIG. 7, but the object of control is different from that of the signal transmission test. The LSI tester 3 sequentially supplies a predetermined test voltage (S11), a clock signal (S12) and a reset signal (S13) to the LSI device 20 under test and the reference LSI device 10.

Then, as in the signal transmission test, the LSI tester 3 confirms the internal statuses of the LSI device 20 under test and the reference LSI device 10, i.e., whether or not the arbitration operation has been completed (S31). If the arbitration has not been completed within a predetermined time period (Yes at S33), the LSI device 20 under test is determined to be defective (S37).

If completion of the arbitration is confirmed (Yes at S32), the LSI tester 3 accesses the logical layer section 12 of the reference LSI device 10 and the logical layer section 22 of the LSI device 20 under test with a low-speed signal to establish transmission and reception settings, respectively (S14). According to the transmission and reception settings, a high-speed signal is transmitted from the physical layer section 11 of the reference LSI device 10 to the physical layer section 21 of the LSI device 20 under test. The physical layer section 21 of the LSI device 20 under test converts the received high-speed signal to a low-speed signal through a conversion process, such as deserialization, or the like, and outputs the low-speed signal as signal reception data to the logical layer section 22.

Then, the LSI tester 3 again confirms the internal status of the LSI device 20 under test, i.e., whether or not the signal receiving operation has been completed (S34). This confirmation is achieved in the same way as in the signal transmission test. If the signal reception has not been completed within a predetermined time period (Yes at S36), the LSI device 20 under test is determined to be defective (S37).

If completion of signal reception is confirmed (Yes at S35), the LSI tester 3 accesses the logical layer section 22 of the LSI device 20 under test to read data received by the LSI device 20 under test. The LSI tester 3 compares the read data with an expected value to determine whether or not the LSI device 20 under test is defective based on the result of comparison (S22).

With the LSI device test according to embodiment 5 as described above, the test time is reduced, and the test cost is decreased. Furthermore, the test is stabilized so that the error of determining a non-defective product to be defective is prevented.

### Embodiment 6

In embodiment 6, a reference LSI device is not provided in an LSI device test unit mounted on a test board but in an LSI tester.

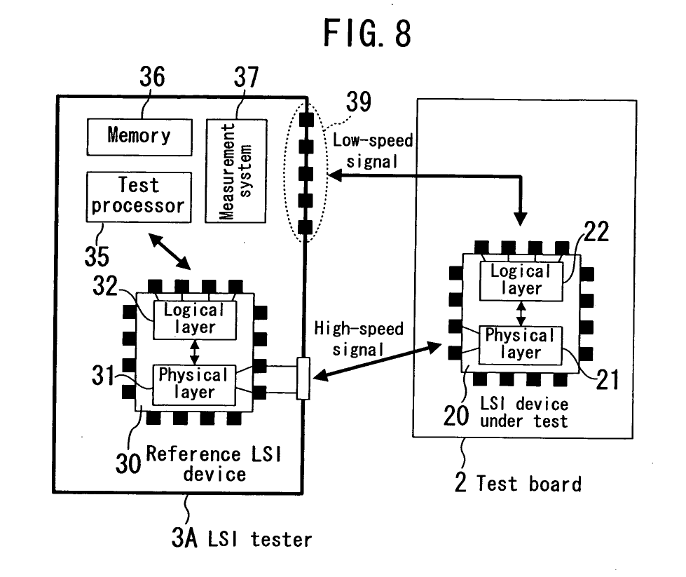

FIG. 8 shows a structure of an LSI device test system according to embodiment 6. In FIG. 8, like elements are denoted by like reference numerals used in FIG. 1. In FIG. 8, an LSI tester 3A includes a reference LSI device (first reference device) 30 which has a physical layer section 31 and a logical layer section 32. The physical layer section 31 of the reference LSI device 30 is electrically connected to a high-speed interface port 38 for establishing high-speed communication with a test board 2. Furthermore, the LSI tester 3A has a low-speed interface port 39 for establishing low-speed communication with a test board 2.

In the first place, a signal transmission test for a physical layer section 21 is described. The LSI tester 3A sequentially supplies a predetermined test voltage, a clock signal and a reset signal to an LSI device 20 under test and the reference LSI device 30 in the LSI tester 3A. Thereafter, the LSI tester 3A accesses a logical layer section 22 of the LSI device 20 under test through the low-speed interface port 39 to establish transmission settings. On the other hand, a test processor 35 of the LSI tester 3A accesses the logical layer section 32 of the reference LSI device 30 to establish reception settings. According to the transmission and reception settings, a high-speed signal is transmitted from the physical layer section 21 of the LSI device 20 under test to the physical layer section 31 of the reference LSI device 30.

The physical layer section 31 of the reference LSI device 30 converts the received high-speed signal to a low-speed signal through a conversion process, such as deserialization, or the like, and outputs the low-speed signal as signal reception data to the logical layer section 32. The test processor 35 of the LSI tester 3A accesses the logical layer section 32 to read the data received by the reference LSI device 30. The test processor 35 then compares the read data with an expected value to determine whether or not the LSI device 20 under test is defective based on the result of comparison.

Next, a signal reception test for the physical layer section 21 is described. The LSI tester 3A sequentially supplies a predetermined test voltage, a clock signal and a reset signal to the LSI device 20 under test and the reference LSI device 30 in the LSI tester 3A. Thereafter, the test processor 35 of the LSI tester 3A accesses the logical layer section 32 to establish transmission settings. On the other hand, the LSI tester 3A accesses the logical layer section 22 through the low-speed interface port 39 to establish reception settings. According to the transmission and reception settings, a high-speed signal is transmitted from the physical layer section 31 of the reference LSI device 30 to the physical layer section 21 of the LSI device 20 under test through the high-speed interface port 38.

The physical layer section 21 of the LSI device 20 under test converts the received high-speed signal to a low-speed signal through a conversion process, such as deserialization, or the like, and outputs the low-speed signal as signal reception data to the logical layer section 22. The LSI tester 3A accesses the logical layer section 22 through the low-speed interface port 39 to read the data received by the LSI device 20 under test. Then, the test processor 35 of the LSI tester 3A compares the read data with an expected value to determine whether or not the LSI device 20 under test is defective based on the result of comparison.

According to embodiment 6, a reference LSI device is provided in a tester, and therefore, the possibility of occurrence of a malfunction due to a dust or shock is reduced. Furthermore, although the cost of the LSI tester 3A increases, it is not necessary to provide the LSI device test unit described in the previous embodiments. Thus, the cost of the test board can be reduced.

In embodiment 6, a reference LSI device described in embodiment 1 is provided in an LSI tester. However, alternatively, the first reference device may be formed by a first reference LSI device having only a physical layer section and a second reference LSI device having only a logical layer section. Still alternatively, the second reference device having only a logical layer section, which has been described in embodiment 2, may be provided in an LSI tester.

In embodiments 1-6, the supply voltages applied to an LSI device under test and a reference LSI device during a test may be identical or may be different. In many cases, an LSI device under test is tested using a plurality of voltages in order to secure the operation voltage range of the LSI device under test. On the other hand, in a reference LSI device, characteristics of a driver and receiver are poor in a low voltage range in many cases. In such a case, the voltage to the reference LSI device is fixed at a low voltage, and the LSI device under test is tested for the two conditions of a high voltage and low voltage, whereby the test conditions are made more stringent, and the test assurance level is increased.

In embodiments 1-6, an LSI device having no margin with respect to assurance specifications may be used as a reference LSI device. That is, an LSI device which provides the lowest performance satisfying the assurance specifications may be used as a reference LSI device. In such a case, an extremely severe test for an LSI device under test is realized, and the test assurance level is increased. Herein, the “assurance specifications” include, for example, the signal voltage amplitude at the time of signal transmission, the sensitivity of a receiver at the time of signal reception, the range of operation frequency, etc.

As described above, according to the present invention, a test of an LSI device incorporating a high-speed interface is realized with an inexpensive low-speed tester and a reference device which has already been confirmed as being non-defective. Accordingly, the test cost can be suppressed.

1. An LSI device test method for testing an LSI device under test which includes a physical layer section having a high-speed interface function, the method comprising the steps of:
mounting the LSI device under test on a test board that is capable of interfacing with an LSI tester, the test board including a first reference device which has a physical layer section and a logical layer section, the physical layer section having a function equivalent to the high-speed interface function, and the logical layer section being connected to the physical layer section and having a low-speed interface function;
electrically connecting the physical layer section of the first reference device and the physical layer section of the LSI device under test to each other;
executing a high-speed communication between the physical layer section of the first reference device and the physical layer section of the LSI device under test by establishing signal transmission and reception settings of the first reference device and the LSI device under test by the LSI tester; and
reading a signal received by the first reference device or the LSI device under test with the LSI tester.

2. The method of claim 1, wherein:
the LSI device under test includes a logical layer section which is connected to the physical layer section of the LSI device under test and which has a low-speed interface function; and
the LSI tester performs establishment of the transmission and reception settings and reading of the received signal through the logical layer section of the first reference device and the logical layer section of the LSI device under test.

3. The method of claim 1, wherein:
the test board includes a second reference device having a logical layer section, the logical layer section being connected to the physical layer section of the LSI device under test and having a low-speed interface function; and
the LSI tester performs establishment of the transmission and reception settings and reading of the received signal through the logical layer section of the first reference device and the logical layer section of the second reference device.

4. The method of claim 1, wherein the supply voltage applied to the first reference device is different from that applied to the LSI device under test.

5. The method of claim 1, wherein prior to establishment of the transmission and reception settings, the LSI tester confirms the internal statuses of the first reference device and the LSI device under test.

6. The method of claim 5, wherein the confirmation of the internal statuses is achieved by reading data from internal storage sections of the first reference device and the LSI device under test.

7. The method of claim 5, wherein when the internal statuses do not settle into predetermined statuses within a predetermined time period, the LSI tester determines that the LSI device under test is defective.

8. The method of claim 1, wherein prior to reading of the received signal, the LSI tester confirms completion of the communication at the first reference device or the LSI device under test.

9. The method of claim 8, wherein the confirmation of completion of the communication is achieved by reading data from an internal storage section of the first reference device or the LSI device under test.

10. An LSI device test system for testing an LSI device under test which includes at least a physical layer section having a high-speed interface function,
the system being structured to be mountable on a test board which is capable of interfacing with an LSI tester and on which the LSI device under test is mounted, and comprising:
a first reference device including a physical layer section having a function equivalent to the high-speed interface function, and a logical layer section which is connected to the physical layer section of the first reference device and which has a low-speed interface function; and
connection means for electrically connecting the physical layer section of the first reference device and the physical layer section of the LSI device under test.

11. The system of claim 10, further comprising a second reference device which is placed between the physical layer section of the LSI device under test and the LSI tester and which includes a logical layer section having a low-speed interface function.

12. The system of claim 10, wherein the first reference device includes
a first reference LSI device having the physical layer section, and
a second reference LSI device having the logical layer section.

13. The system of claim 10, wherein the connection means includes means for branching a signal path formed between the first reference device and the LSI device under test.

14. The system of claim 10, further comprising a clock generator for supplying a clock to the LSI device under test and the first reference device independently of the operation of the LSI tester.

15. The system of claim 10, wherein the first reference device is already confirmed as being non-defective.

16. The system of claim 15, wherein the first reference device provides the lowest performance satisfying assurance specifications.

17. An LSI tester for testing an LSI device under test which includes at least a physical layer section having a high-speed interface function,
the LSI tester being capable of interfacing with a test board on which the LSI device under test is mounted, and comprising:
a first reference device including a physical layer section which has a function equivalent to the high-speed interface function, and a logical layer section which is connected to the physical layer section of the first reference device and which has a low-speed interface function; and
a high-speed interface port which is electrically connected to the physical layer section of the first reference device and which executes a high-speed communication with the test board.

18. The LSI tester of claim 17, further comprising:
a low-speed interface port for executing a low-speed communication with the test board; and
a second reference device including a logical layer section which is connected to the low-speed interface port and which has a low-speed interface function.
